(19) United States
(12) Patent Application Publication
(10) Pub. No.: US 2018/0177072 A1
(43) Pub. Date: Jun. 21, 2018

(54) ELECTRONICS CHASSIS ASSEMBLY

(71) Applicant: GE AVIATION SYSTEMS, LLC, GRAND RAPIDS, MI (US)

(72) Inventors: Luis Javier Pando Rodriguez, Queretaro (MX); Armando Herrera Velázquez, Cheran (MX); Luis Antonio Mendoza Gómez, Queretaro (MX); Jorge Alberto Martínez Vargas, Queretaro (MX); Federico Taboada Reyes, Queretaro (MX); Diego Hernandez Guerra, Queretaro (MX); Ramon Morales Rueda, Queretaro (MX); Aquiles Tiscareño Macias, Queretaro (MX)

(21) Appl. No.: 15/383,607

(22) Filed: Dec. 19, 2016

(51) Int. Cl. H05K 7/20; H05K 9/00; F28F 21/02; F28F 21/08

(52) U.S. Cl. CPC H05K 7/202; H05K 7/20409; F28F 2255/06; F28F 21/02; F28F 21/084; H05K 9/0081

(57) ABSTRACT

A method and apparatus for heat-dissipation in an electronics chassis can include a housing having an interior and exterior, at least two walls, at least one of which is a thermally conductive wall, a heat spreader operably coupled to at least a portion of the housing to dissipate or spread heat from a heat producing component.

### BACKGROUND OF THE INVENTION

Contemporary aircrafts use avionics in order to control the various equipment and operations for flying the aircraft. The avionics can include electronic components carried by a circuit board. The avionics or the circuit boards can be stored in or on an electronic chassis, for example an avionics chassis, which performs several beneficial functions, some of which are: electrically shielding the avionics from electromagnetic interference (EMI), protecting the avionics from lightning strikes, dissipating the heat generated by the avionics or electronic components, and protecting the avionics from environmental exposure.

### BRIEF DESCRIPTION OF THE INVENTION

In one aspect, the present disclosure relates to an electronics chassis assembly, including a housing having an interior and exterior, including at least two walls, at least one of which is a thermally conductive wall having a first side and a second side opposite the first side a casing operably coupled to at least a portion of the housing and a set of graphite fins defining a heat sink thermally coupled to the thermally conductive wall.

In another aspect, the present disclosure relates to a finned heat exchanger, including a housing, comprised of an aluminum-graphene composite, configured to transfer heat from a heat producing component and a set of graphite fins adjacent the housing.

In yet another aspect, the present disclosure relates to an avionics heat exchanger assembly, including an aluminum chassis, at least one graphene foil heat spreader operably coupled to the aluminum chassis and configured to be operably coupled to a heat producing component, and a set of graphite fins thermally coupled to one of the aluminum chassis or the at least one graphene foil heat spreader and extending therefrom.

### BRIEF DESCRIPTION OF THE DRAWING

In the drawings:

FIG. 1 is a perspective view of an aircraft having an electronics chassis in accordance with various aspects described herein.

FIG. 2 is an exploded view of the electronics chassis of FIG. 1, in accordance with various aspects described herein.

FIG. 3 is a perspective view of an electronics chassis assembly in accordance with various aspects described herein.

FIG. 4 is a cross-sectional view taken along the line 4-4 of a portion of the electronics chassis shown in FIG. 3, in accordance with various aspects described herein.

FIG. 5 is an electronics chassis of FIG. 1, in accordance with various aspects described herein.

### DETAILED DESCRIPTION OF THE INVENTION

Aspects of the disclosure describe an approach to utilize a combination of graphite, graphene, aluminum, and aluminum-graphite composite materials to provide an electronics chassis with a heat sink having increased heat dissipation with decreased weight when compared to current aluminum alloy heat sinks.

While “a set of” various elements will be described, it will be understood that “a set” can include any number of the respective elements, including only one element. Additionally, all directional references (e.g., radial, axial, upper, lower, upward, downward, left, right, lateral, front, back, top, bottom, above, below, vertical, horizontal, clockwise, counterclockwise) are only used for identification purposes to aid the reader's understanding of the disclosure, and do not create limitations, particularly as to the position, orientation, or use thereof. Connection references (e.g., attached, coupled, connected, and joined) are to be construed broadly and can include intermediate members between a collection of elements and relative movement between elements unless otherwise indicated. As such, connection references do not necessarily infer that two elements are directly connected and in fixed relation to each other. The exemplary drawings are for purposes of illustration only and the dimensions, positions, order and relative sizes reflected in the drawings attached hereto can vary.

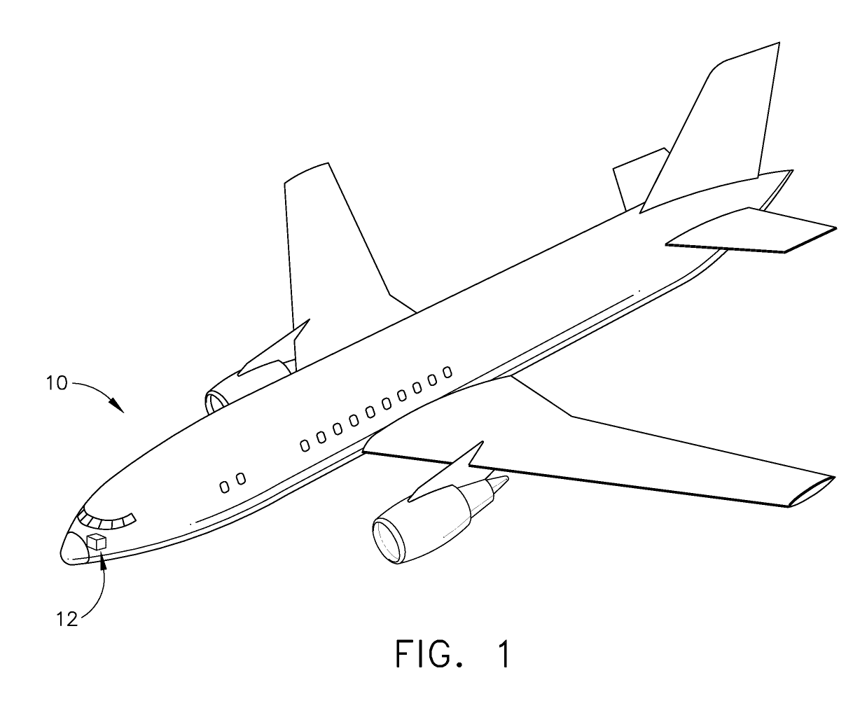

FIG. 1 schematically illustrates an aircraft 10 with an on-board electronics chassis assembly 12 (shown in phantom) for housing avionics or avionics components for use in the operation of the aircraft 10. The electronics chassis assembly 12 can house a variety of avionics elements and protects them against contaminants, electromagnetic interference (EMI), radio frequency interference (RFI), vibrations, and the like. Alternatively or additionally, the electronics chassis assembly 12 can have a variety of avionics mounted thereon. It will be understood that the electronics chassis assembly 12 can be located anywhere within the aircraft 10, not just the nose as illustrated. While illustrated in a commercial airliner, the electronics chassis assembly 12 can be used in any type of aircraft, for example, without limitation, fixed-wing, rotating-wing, rocket, commercial aircraft, personal aircraft, and military aircraft. Furthermore, aspects of the disclosure are not limited only to aircraft aspects, and can be included in other mobile and stationary configurations. Non-limiting example mobile configurations can include ground-based, water-based, or additional air-based vehicles.

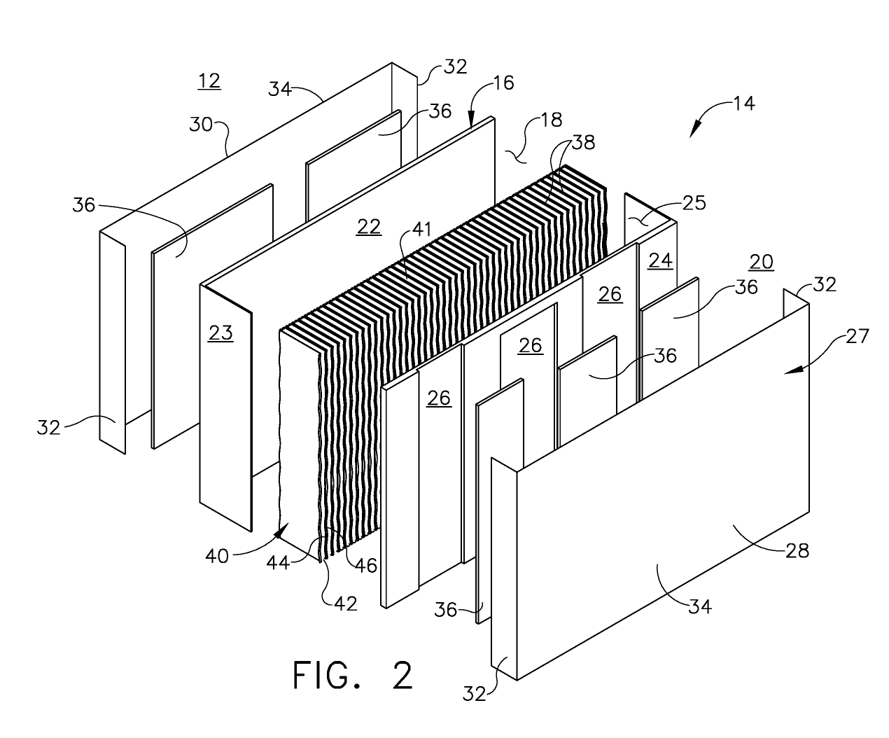

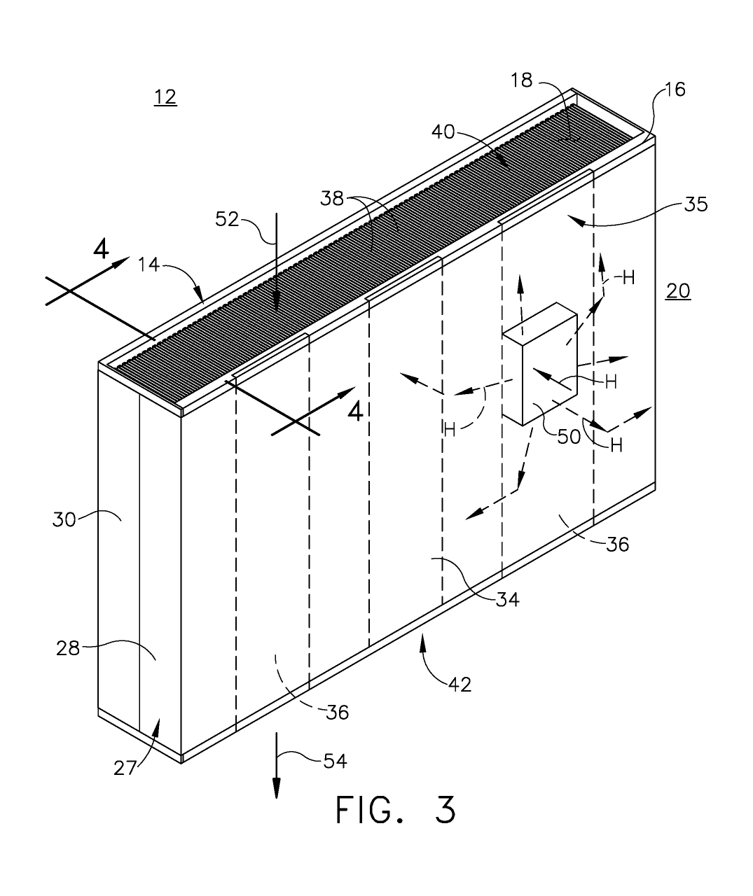

FIG. 2 illustrates an exploded view of an exemplary electronics chassis assembly 12 according to an aspect of the present disclosure. A finned heat exchanger 14 including a housing 16 defining an interior 18 and an exterior 20 can be included in the electronics chassis assembly 12. The electronics chassis assembly 12 can therefore include, but is not limited to, an avionics heat exchanger assembly. At least two opposing sidewalls 22, 24 each of which can terminate in an aluminum portion 23, 25 can be part of the housing 16. It is further contemplated that an aluminum housing is the entire housing 16. At least one recessed portion 26, illustrated as three recessed portions 26 in the sidewall 24 and two recessed positions 26 in the sidewall 22. At least one opposing side wall 22, 24 is a thermally conductive wall. It is further contemplated that the sidewalls 22, 24 are formed from an aluminum-graphene composite material forming an enclosure having an increased tensile strength of 12% to 14.7% over pure aluminum this would lead to a consequent weight reduction. In this manner, the sidewalls 22 and 24 can form base surfaces that are configured to transfer heat from a heat producing component 50 (FIG. 3).

A casing 27 has also been illustrated and includes a first heat spreader 28 and a second heat spreader 30. The first and second heat spreaders 28, 30 can be located adjacent the housing 16. In the illustrated example, the first and second heat spreaders 28, 30 include distal ends 32. The distal ends 32 of the first and second heat spreaders 28, 30 can be adjacent each other such that the first and second heat spreaders 28, 30 collectively enclose the housing 16. It is contemplated that at least one of the first heat spreader 28 or the second heat spreader 30 is a graphene foil heat spreader 34 and that both can be a graphene foil heat spreaders 34.

A set of graphite foam panels 36 can be located between the thermally conductive sidewalls 22, 24 and the graphene foil heat spreader 34. A graphite foam panel 36 can at least partially sit in the recessed portion 26. In the illustrated example, two graphite foam panels 36 are located between the thermally conductive side wall 22 and the graphene foil heat spreader 34 and three graphite foam panels 36 are located between the thermally conductive side wall 24 and the graphene foil heat spreader 34. It will be understood that any number of graphite foam panels can be included and that the graphite foam panels need not be included on both sidewalls.

A heat sink 40 is ensconced in the housing 16. An inlet 41 of the housing 16 and an outlet 42 of the housing 16 are formed along the entire length of the heat sink where the housing 16 is opened to the exterior 20. It should be understood that while the inlet 41 and outlet 42 are illustrated along the entire length, other variations of an inlet or outlet are contemplated. While illustrated as occupying the entire interior 18, it can be contemplated that the heat sink 40 can occupy only a portion of the interior 18. For example, by way of non-limiting example, the portion is only half of the interior 18.

A set of graphite fins 38 together define the heat sink 40 and in turn the finned portion of the finned heat exchanger 14. Fins of the set of graphite fins 38 can comprise a graphite foam structure having first and second planar sides 44, 46. The set of graphite fins 38 can be formed by a highly oriented, low density open-cell graphite foam structure with a mass density of 0.2 to 0.6 g/cc, or a 75% reduction when compared to an aluminum alloy mass density of 1.5 to 2.5 g/cc. It should be appreciated that the set of graphite fins 38 need not extend the full length of the sidewalls 22, 24, and can be organized in sets of rows or columns along the sidewalls 22, 24, in non-limiting examples. Additionally, the set of graphite fins 38, rows, or columns can be aligned, unaligned, offset, patterned, or otherwise organized to improve heat transfer and dissipation. Manufacture of the fins can be accomplished, for example, by additive manufacturing such as 3D printing including direct metal laser melting.

Turning to FIG. 3 a perspective assembled view of the electronics chassis assembly 12 illustrates the housing 16 and heat sink 40 with the set of graphite foam panels 36 (shown in phantom) between the side wall 24 of the housing 16 and the graphene foil heat spreader 34.

In the exemplary illustration, at least one heat producing component 50 can be mounted to the graphene foil heat spreader 34. The heat producing component 50 can be, by way of non-limiting example, a circuit card assembly such as a printed circuit board (PCB) or an electronic circuit board. A non-limiting list of additional heat producing components that can be integral with the PCB include electrical circuitry, power electronics such as capacitors, transformers, or the like, a semiconductor chip, a processor, memory chips, or the like.

Under operating circumstances, high amount of heat generated by the heat producing component 50 is transferred by conduction along and across, by way of non-limiting example thermally conductive paths H, the graphene heat spreader 34, the graphite foam panels 36, and the aluminum opposing sidewalls 22, 24, to the set of graphite fins 38. The thermal conductivity of graphite is 240 W/mK and therefore heat is transferred at a quicker rate along the thermally conductive path H when compared to a standard aluminum structure where aluminum alloy has a lower thermal conductivity of 152 W/mK. The set of graphite fins 38 can be under contact pressure between the opposing sidewalls 22, 24, or adhere to the opposing sidewalls 22, 24 with by way of non-limiting example, thermally conductive adhesive.

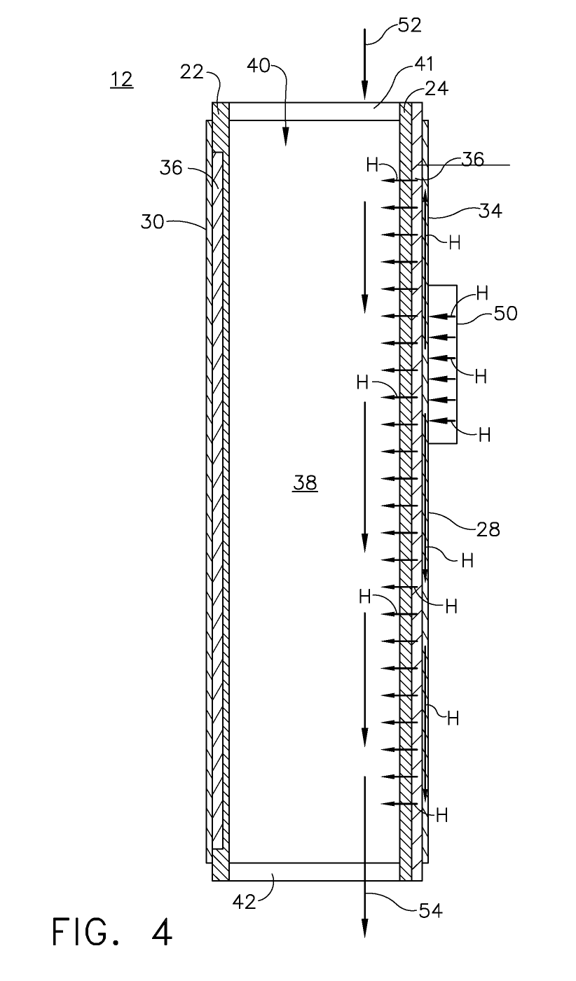

A cross-section of the electronics chassis 12 is illustrated in FIG. 4. In order to provide heat dissipation at the set of graphite fins 38, a flow of fluid 52, by way of non-limiting example cooling air, can be provided along the set of graphite fins 38 to remove heat through convection. Heat collected in the heat sink 40 is dissipated or flushed out by the flow of fluid 52 introduced at the inlet 41 moving heat away from the electronics chassis assembly 12 where it exits as a hot fluid flow 54 at the outlet 42.

While a set of graphite fins 38 are contemplated, a number of heat-dissipating graphite elements or heat-dissipating graphite configurations can be utilized by the heat sink 40 to remove or dissipate at least a portion of heat generated by the heat producing component and its surroundings within the electronics chassis assembly 12.

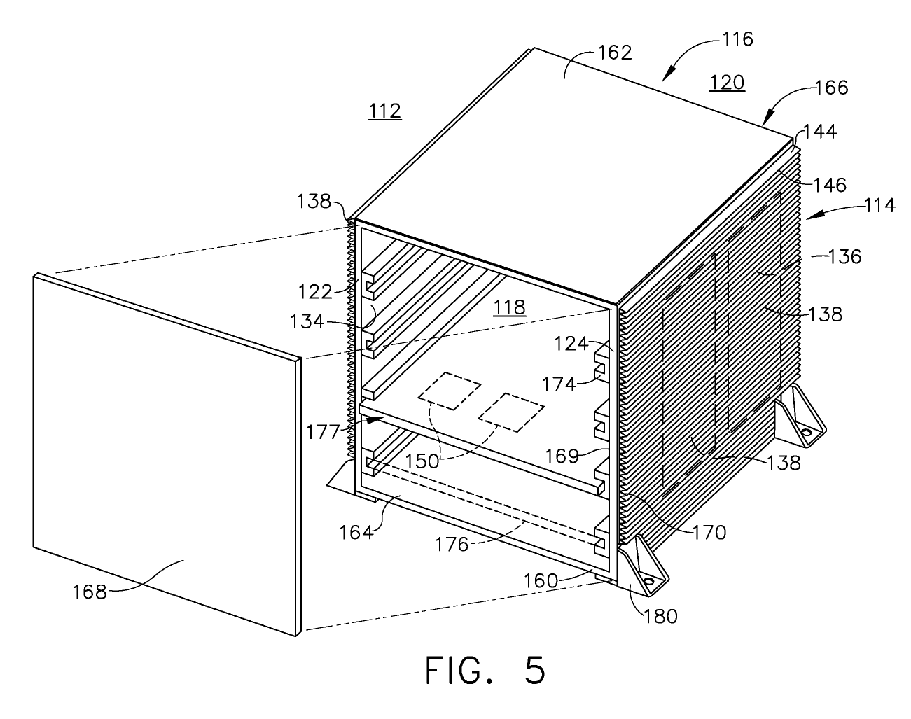

FIG. 5 illustrates an alternative electronics chassis 112 according to various aspects described herein. The electronics chassis 112 is similar to the electronics chassis 12 described herein, therefore like parts will be identified with like numerals increasing by 100 with it being understood that the description of the like parts of the various aspects described herein applies to the additional embodiments, unless otherwise noted.

The electronics chassis 112 includes a chassis housing 116 defining an interior 118 and exterior 120 of the electronics chassis 112. The electronics chassis 112 can include a chassis frame 160 having a top cover 162, a bottom wall 164, a back wall 166, and opposing sidewalls 122, 124, each of which can include recesses (not shown) in which a graphite foam panel 136, shown in phantom, can be received. The frame 160 can further include a removable front cover 168, providing access to the interior 118 of the electronics chassis 112 when removed, and at least partially restricting access to the interior 118 when coupled or mounted to the frame 160. The sidewalls 122, 124 can include an interior surface 169 and an exterior surface 170 and can be at least partially encased in a thermally conductive graphene foil heat spreader 134.

A set of graphite fins 138, can project from the exterior surface 170 of the sidewalls 122, 124. While the set of graphite fins 138 are shown on the sidewalls 122, 124, the set of graphite fins 138 can be disposed on any exterior portion of the chassis 112, such as the top cover 162 or the bottom wall 164 in non-limiting examples. While the set of graphite fins 138 are shown extending fully along the sidewalls 122, 124, it should be appreciated that the set of graphite fins 138 need not extend the full length of the sidewalls 122, 124, and can be organized in other non-limiting configurations described previously.

The electronics chassis 112 can further include a set of card rails 174 within the interior 118 and supported by the interior surface 169 of the sidewalls 122, 124. The set of card rails 174 can be horizontally aligned on the interior surfaces 169 and spaced on opposing sidewalls 122, 124 to define effective card slots 176 (illustrated by the dashed lines) for receiving at least a portion of an avionics system card 177. Each avionics card 177 can include at least one heat producing component 150. While only an avionics system card 177 is shown, the electronics chassis 112 can be configured to house, support, or include a set of avionics system cards 177.

Each avionics card 177 can be formed from a heat conductive material such that heat can move from the heat producing component to the heat spreader 134, through the graphite foam panel 136 and away from the electronics chassis 112 through the graphite fins 138. By way of non-limiting example, it is contemplated that air can be provided along the graphite fins 138 to move the heat away. It is further contemplated that heat introduced to exterior 120 of the electronics chassis 112 will dissipate by convection as well.

The electronics chassis 112 is illustrated including a set of mounting feet 180 extending from the chassis housing 116 to facilitate mounting the electronics chassis 112 to the aircraft 10 by means of bolts or other conventional fasteners. Further, the mounting feet 180, can function as an electrical ground to ground the electronics chassis to the frame of the aircraft 10. While mounting feet 180 are shown in this example, the electronics chassis 112 can be used with many types of attachment mechanism.

Thus, aspects of the disclosure describe an electronics chassis having a portion of a thermal plane including a graphene foil heat spreader, graphite foam panels, and fins extending beyond the chassis, and wherein heat generated by a heat producing component can be dissipated by such structures. Alternatively, the graphene foil heat spreader can be located between the wall and the fins. It is also contemplated that the heat spreader, base surface, foam and fins can be combined in any arrangement suitable for dissipating heat from the heat producing component.

One advantage that can be realized is superior cooling capabilities compared with conventional systems. The electronics chassis assemblies 12, 112 described herein can run much cooler with the additional conductive paths provided by the graphene foil heat spreader 34, 134 and graphite foams panels 36, 136. In existing power conversion systems, the mechanical components represent almost 27% of the overall weight, leaving only 36% of the mechanical weight budget to be invested in thermal management systems. Graphite and Graphene based heat exchangers may reduce the overall weight of existing aluminum heat exchangers by 30% while improving thermal conductivity.

A preliminary study was performed in which an aluminum heatsink was used as a baseline and a 300 W hot spot was added, the heatsink was analyzed with a finite element under different configurations of graphene. A thermal analysis of the heatsink and the hot spot without graphene was performed. Incrementally, graphene foils were added underneath the hot spot acting as thermal spreaders. The results of this experiment demonstrated a 7% temperature reduction with the use of graphene foils as thermal spreaders. Graphene and graphite can be embedded with the aluminum structure to preserve mechanical integrity. Alternatively, stand-alone and graphite structures are contemplated.

Higher power density in a smaller space has been an increasing requirement of power generating devices. New power generation and conversion units have requirements for new materials and more efficient thermal management. While aluminum alloys are a common lightweight material used in current heat exchanger design, the increasing requirements have resulted in aluminum and copper becoming a constraint. Utilizing graphite and graphene contributes to the ability design for increased power, and maintain or even decrease volume.

By decreasing the material density, the electronics chassis assembly described herein lends itself to an increased power density while taking up the same or less volume. An increased power density allows for increased computational power or increased sensor or emitter power supported within the physically-constrained space, weight-constrained space, or volume-constrained space.

Many other possible configurations in addition to those shown in the above figures are contemplated by the present disclosure. In one non-limiting example, the heat sink 40 could be mounted to or combined with the electronics chassis assembly 112 to form a hybrid electronics chassis assembly. To the extent not already described, the different features and structures of the various aspects can be used in combination with others as desired. That one feature cannot be illustrated in all of the aspects is not meant to be construed that it cannot be, but is done for brevity of description. Thus, the various features of the different aspects can be mixed and matched as desired to form new aspects, whether or not the new aspects are expressly described. Combinations or permutations of features described herein are covered by this disclosure.

This written description uses examples to disclose aspects of the invention, including the best mode, and also to enable any person skilled in the art to practice aspects of the invention, including making and using any devices or systems and performing any incorporated methods. The patentable scope of the invention is defined by the claims, and can include other examples that occur to those skilled in the art. Such other examples are intended to be within the scope of the claims if they have structural elements that do not differ from the literal language of the claims, or if they include equivalent structural elements with insubstantial differences from the literal languages of the claims.

What is claimed is:

1. An electronics chassis assembly, comprising:
a housing having an interior and exterior, comprising at least two walls, at least one of which is a thermally conductive wall;
a heat spreader operably coupled to at least a portion of the housing; and
a set of graphite fins defining a heat sink thermally coupled to the thermally conductive wall.

2. The electronics chassis assembly of claim 1 wherein the at least two walls include aluminum walls.

3. The electronics chassis assembly of claim 1 wherein the housing comprises at least one graphene foil heat spreader.

4. The electronics chassis assembly of claim 1, further comprising a set of graphite foam panels located between the thermally conductive wall of the housing and the heat spreader.

5. The electronics chassis assembly of claim 4 wherein the thermally conductive wall comprises at least one recessed portion and the graphite foam is at least partially located therein.

6. The electronics chassis assembly of claim 1, further comprising at least one heat producing component thermally coupled with the thermally conductive wall.

7. The electronics chassis assembly of claim 1 wherein a fin of the set of graphite fins comprises a graphite foam structure having a first planar side and a second planar side.

8. The electronics chassis assembly of claim 1 wherein the at least two walls include aluminum-graphene composite walls.

9. The electronics chassis assembly of claim 1 wherein the set of graphite fins comprise a graphite foam having a mass density of 0.2 to 0.6 g/cc.

10. A finned heat exchanger, comprising:
a base surface, comprised of an aluminum-graphene composite, configured to transfer heat from a heat producing component; and
a set of graphite fins adjacent the base surface.

11. The finned heat exchanger of claim 10 wherein the set of graphite fins comprise at least one graphite foam structure having a first planar side and a second planar side.

12. The finned heat exchanger of claim 11 wherein the graphite foam structure has a mass density of 0.2 to 0.6 g/cc.

13. The finned heat exchanger of claim 10 wherein the base surface comprises an enclosure having an increased tensile strength of 12% to 14.7% over pure aluminum.

14. The finned heat exchanger of claim 10, further comprising at least one graphene foil heat spreader operably coupled to at least a portion of the base surface.

15. The finned heat exchanger of claim 14, further comprising at least one graphite foam panel located between a first portion of the base surface and a second portion of the at least one graphene foil heat spreader.

16. An avionics heat exchanger assembly, comprising:
an aluminum chassis;
at least one graphene foil heat spreader operably coupled to the aluminum chassis and configured to be operably coupled to a heat producing component; and
a set of graphite fins thermally coupled to one of the aluminum chassis or the at least one graphene foil heat spreader and extending therefrom.

17. The avionics heat exchanger assembly of claim 16, further comprising at least one graphite foam panel located between a first portion of the aluminum chassis and a second portion of the at least one graphene foil heat spreader.

18. The avionics heat exchanger assembly of claim 16 where a flow of fluid is forced past the set of graphite fins.

19. The avionics heat exchanger assembly of claim 16 wherein a fin of the set of graphite fins comprises at least one graphite foam structure having a first planar side and a second planar side.

20. The avionics heat exchanger assembly of claim 19 wherein the graphite foam structure has a mass density of 0.2 to 0.6 g/cc.
